(19) United States
(12) Patent Application Publication
(10) Pub. No.: US 2026/0047148 A1
(43) Pub. Date: Feb. 12, 2026

(54) PLANAR JFET WITH SHIELDED SOURCE

(71) Applicant: Microchip Technology Incorporated, Chandler, AZ (US)

(72) Inventors: Shesh Mani Pandey, Gilbert, AZ (US); George Dorman, Chandler, AZ (US)

(73) Assignee: Microchip Technology Incorporated, Chandler, AZ (US)

(21) Appl. No.: 19/202,882

(22) Filed: May 8, 2025

Related U.S. Application Data
(60) Provisional application No. 63/682,255, filed on Aug. 12, 2024.

(51) Int. Cl. H10D 30/83; H10D 30/01; H10D 62/00; H10D 62/17

(52) U.S. Cl. CPC H10D 30/831; H10D 30/0515; H10D 62/01; H10D 62/343

(57) ABSTRACT

A field-effect transistor with a shielded source, and a method of making the same. A volume of semiconductor material includes first and second vertically spaced ends and first and second laterally spaced sides. First and second laterally spaced gates are provided in the volume of semiconductor material. A source is located at the first end between the first and second gates, a drain is provided, and a channel extends therebetween. The first gate includes a lower first gate portion spaced below and extending beneath the source so as to create a turn in the channel around the lower first gate portion.

### RELATED APPLICATION

The present U.S. non-provisional patent application is related to and claims priority benefit of an earlier-filed U.S. provisional patent application titled “Planar JFET with Shielded Source,” Ser. No. 63/682,255, filed Aug. 12, 2024. The entire content of the identified earlier-filed application is incorporated by reference as if fully set forth herein.

### FIELD

The present disclosure relates to junction field-effect transistors and methods of making them, and, more particularly, the various examples described herein concern a planar junction field-effect transistor with a shielded source, and a method of making a planar junction field-effect transistor with a shielded source.

### BACKGROUND

A junction field-effect transistor (JFET) is an active, voltage-controlled semiconductor device, in which varying an electrical voltage between a gate and a source controls an electrical current flowing through a semiconductor channel between a drain and the source. Applications for JFETs include amplifiers, switches, resistors, regulators, oscillators, and choppers. It is generally desirable to improve the performance and reduce the cost of JFETs, but it can be difficult to do so.

This background discussion is intended to provide related information, and is not necessarily prior art.

### SUMMARY

Examples provide a field-effect transistor with a shielded source, and a method of making a field-effect transistor with a shielded source. More specifically, a lower first gate portion extends beneath a source so as to create a turn in a channel around the lower first gate component. Examples advantageously provide improved performance, including improved robustness, a reduced reverse bias leakage current, and a higher breakdown voltage for the JFET, and reduced cost.

In an example, a field-effect transistor may include a volume of semiconductor material, a source, a drain, a channel, and first and second gates. The volume of semiconductor material may include vertically spaced apart first and second ends and laterally spaced apart first and second sides. The source may be located at the first end of the volume of semiconductor material. The channel may extend between the source and the drain. The source may be located between the gates. The first gate may include a lower first gate portion spaced below and extending beneath the source so as to create a turn in the channel around the lower first gate portion.

The preceding example may further include any one or more of the following features. The drain may be located at the second end of the volume of semiconductor material, such that the lower first gate portion may be vertically positioned at least in part between the source and the drain to thereby shield the source. The second gate may include a lower second gate portion spaced laterally apart from the lower first gate portion, wherein the channel may pass between the lower first gate portion and the lower second gate portion. The lateral spacing of the lower first gate portion from the lower second gate portion may be between one-half (0.5) and one-and-one-half (1.5) micrometers. The lower limit of the lower first gate portion may be coplanar with a lower limit of the lower second gate portion. The first gate may include an upper first gate portion extending between the lower first gate portion and the first end of the volume of semiconductor material. The second gate may include an upper second gate portion extending between the lower second gate portion and the first end of the volume of semiconductor material. The source may be laterally spaced from the upper second gate portion. The source may abut the upper first gate portion. The spacing between the source and the upper second gate portion may be less than a spacing between the lower first and second gate portions. The lower limit of the lower first gate portion may be coplanar with the lower limit of the lower second gate portion. The first and second gates may be in direct contact with the channel, such that the field-effect transistor is a junction field-effect transistor. The field-effect transistor may have a planar configuration, and the first and second gates may be located at the first end of the volume of semiconductor material. The vertical spacing between the source and the lower first gate portion may be between one-half (0.5) and three-quarters (0.75) micrometers.

In another example, a method of making a junction field-effect transistor with a shielded source may include the following operations. A volume of semiconductor material may be grown to include vertically spaced apart first and second ends and laterally spaced apart first and second sides. A first gate may be implanted at the first side of the volume of semiconductor material. A second gate may be implanted at the second side of the volume of semiconductor material spaced apart from the lower first gate component. A source may be implanted at the first end of the volume of semiconductor material between the first and second gates. The step of implanting the first gate may include implanting a lower first gate portion at a location spaced below and extending beneath the source so as to create a turn in the channel around the lower first gate portion.

The preceding example may further include any one or more of the following features. The step of providing the drain may include providing a substrate material, and the step of growing the volume of semiconductor material may include growing the volume of semiconductor material on the substrate, with the substrate material forming the drain at the second end of the volume of semiconductor material, and the lower first gate portion is vertically positioned at least in part between the source and the drain to thereby shield the source. The step of implanting the first gate may include implanting an upper first gate portion at the first side of the volume of semiconductor material, with the upper first gate portion extending between the lower first gate portion and the first end of the volume of semiconductor material. The step of implanting the second gate may include implanting a lower second gate portion spaced from the lower first gate portion, and implanting a upper second gate portion spaced from the upper first gate portion, with the upper second gate portion extending between the lower second gate portion and the first end of the volume of semiconductor material. The step of implanting the source may include abutting the source against the upper first gate portion and spacing the source from the upper second gate portion. The steps of implanting the source and the lower first gate portion may be performed so that a vertical spacing between the source and the lower first gate portion is between one-half (0.5) and three-quarters (0.75) micrometers. The steps of implanting the lower first and second gate portions may be performed such that a lower limit of the lower first and second gate portions are coplanar. The steps of implanting the lower first and second gate portions may be performed such that a horizontal spacing between the lower first and second gate portions is between one-half (0.5) and one-and-one-half (1.5) micrometers.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of an example of a planar JFET with a shielded source;

FIG. 2 is a flowchart of operations in an example of a method of making a planar JFET with a shielded source;

FIG. 3A is a cross-sectional elevation view of the result of an operation in the method of FIG. 2, wherein an N-epitaxial layer is shown on an N+ substrate and first and second P+ structures are implanted in the N-epitaxial layer;

FIG. 3B is a cross-sectional elevation view of the result of an operation in the method of FIG. 2, wherein first and second P++ structures are implanted;

FIG. 3C is a cross-sectional elevation view of the result of an operation in the method of FIG. 2, wherein an N+ structure is implanted;

FIG. 3D is a cross-sectional elevation view of the result of an operation in the method of FIG. 2, wherein electrical terminals are added; and

FIG. 4 is a cross-sectional elevation view of a plurality of instances of the planar JFET of FIG. 1.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Broadly, examples provide a field-effect transistor with a shielded source, and a method of making a field-effect transistor with a shielded source. More specifically, a lower first gate portion extends beneath a source so as create a turn in a channel around the lower first gate portion. Examples advantageously provide improved performance, including improved robustness, a reduced reverse bias leakage current, and a higher breakdown voltage for the transistor, and reduced cost.

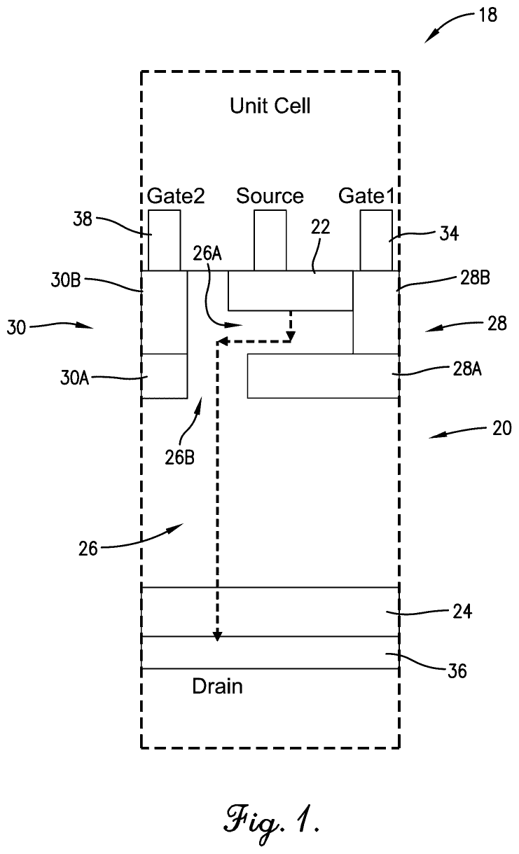

Referring to FIG. 1, an example of a planar junction field-effect transistor (JFET) 18 with a shielded source may include a volume of semiconductor material 20, a source 22, a drain 24, a channel 26, a first gate 28, and a second gate 30, wherein the first gate 28 provides the shield for the source 22. The volume of semiconductor material 20 may include a first end, a vertically spaced opposite second end, a first side, and a laterally spaced opposite second side. The volume of semiconductor material 20 may be constructed from or include an N-type material. The source 22 may be located at or near a first end of the volume of semiconductor material 20 and provide an entrance for majority charge carriers (e.g., electrons for N-channel) into the channel 26. The source 22 may include N+ material. The drain 24 may be located at or near a second end of the volume of semiconductor material 20, spaced apart from the source 22, and provide an exit for the majority charge carriers from the channel 26. The drain 22 may include N+ material. According to some aspects, the drain may alternatively be located at the first end of the volume of semiconductor material. The channel 26 may be a region extending between the source 22 and the drain 24 and through which the majority charge carriers move, i.e., through which electric current flows. It will be appreciated that the majority charge carriers, which in the case of an N-type FET, are electrons, flow from the source 22 to the drain 24, and the conventional current, Id, flows from the drain 24 to the source 22.

The first gate 28 may include a lower first gate portion (or component) 28A generally located at the first side of the volume of semiconductor material 18 and partially extending beneath the source 22. The first gate 28 may also include an upper first gate portion (or component) 28B generally located above the lower first gate component 28A. The upper first gate component 28B may be located adjacent to and abutting the source 22. The lower first gate component 28A may provide the “shield” for the source 22. The lower first gate component 28A may be constructed from or include P+ material, and the upper first gate component 28B may be constructed from or include a P++ material.

As seen in the figures, the source 22 and the extension of the lower first gate component 28A into the channel beneath the source 22 may define a horizontal portion 26A of the channel 26, and the lower first gate component 28A and the lower second gate component 30A may define a vertical portion 26B of the channel 26. Thus, the positions of these structures create a turn in the channel 26 around the lower first gate component 28A and then between the lower first and second gate components 28A, 30A. A vertical spacing between the source 22 and the lower first gate component 28A may be determined by the breakdown voltage, BVgs. This vertical spacing may be approximately between one-half (0.5) and three-quarter (0.75) micrometers. A horizontal spacing of the lower first gate component 28A from the lower second gate component 30A may be between one-half (0.5) and one-and-one-half (1.5) micrometers.

The second gate 30 may be generally located at the second side of the volume of semiconductor material 18, opposite the first gate 28. The second gate 30 may include a lower second gate portion (or component) 30A spaced apart from the lower first gate component 28A and generally lower than the source 22, and an upper second gate portion (or component) 30B located above the lower second gate component 30A and spaced apart from the source 22. The lower second gate component 30A may be constructed from or include P+ material, and the upper second gate component 30B may be constructed from or include P++ material. The lower limits of the lower components 28A, 30A of the first and second gates 28, 30 may be approximately coplanar so as to be easier to manufacture. Thus, the lower first gate component 28A extends beneath the source 22 so as to be positioned partially between the source 22 and the drain 24 and shields the source 22 and creates a turn in the channel 26 around the lower first gate component 28A, and the channel 26 passes between the lower first and second gate components 28A, 30A.

The source 22 and the first gate 28 may share a first electrical terminal 34, the drain 24 may have a second electrical terminal 36, and the second gate 30 may have a third electrical terminal 38 for facilitating connections to appropriate voltage sources. As noted, the source 22 may abut the upper first gate portion 28B but be spaced laterally from the upper second gate portion 30B. Further, the first and second gates 28, 30 may have vertical symmetry such that the lower limits of the lower first and second gate portions 28A, 30A are coplanar. However, according to some aspects, the lower limits of the lower first and second gate portions may alternatively be vertically spaced (vertically asymmetric).

In operation, an input voltage, Vds, may be applied across the first and second electrical terminals to cause electron drift/movement from the source 22 to the drain 24, and a control voltage, Vgs, may be applied across the first and third electrical terminals to control the width of the depletion region at the PN junctions where the charge carriers of the P- and N-type materials diffuse into each other, which “depletes” the available concentrations of majority charge carrier in each material, and thereby controls the current, Id, from the drain 24 to source 22. Thus, the source 22, the first gate 28, and the second gate 30 may cooperate under Vgs to control the current, Id, through the channel 26. If Vgs=0 V and Vds>0 V, electrons drift, or move, from the source to the drain, resulting in a current, Id, from the drain 24 to the source 22, and increased depletion regions at the PN junctions. If Vds=pinch-off voltage (Vp), then the depletion regions increase in size and grow sufficiently close to each other across the channel 26 that the current, Id, through the channel cannot increase and so is at its maximum, Id=(max drain current (Idss)). In the present examples, the shielding of the source 22 by the lower first gate component 28A reduces a reverse bias leakage current and provides a higher breakdown voltage (BVgs) for the JFET 18.

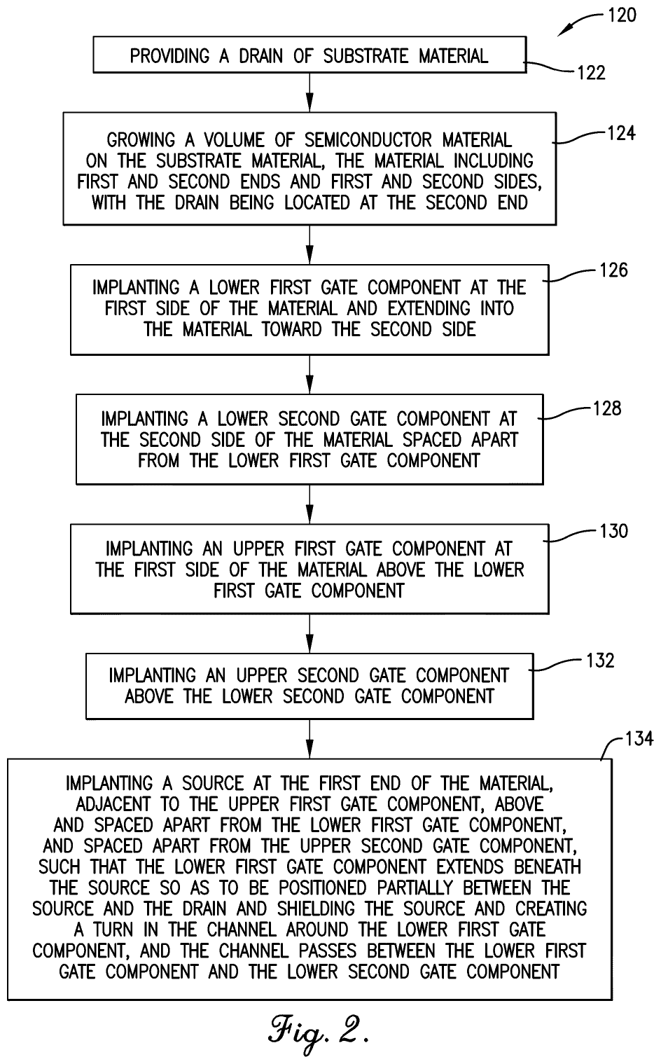

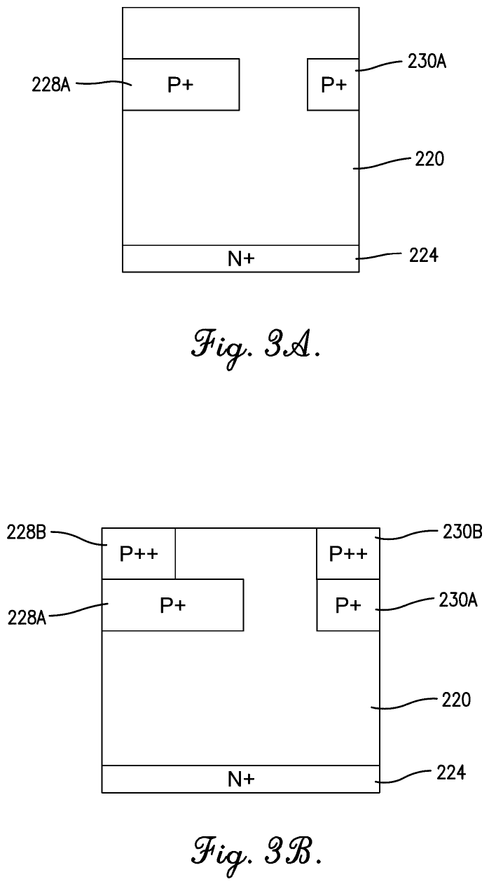

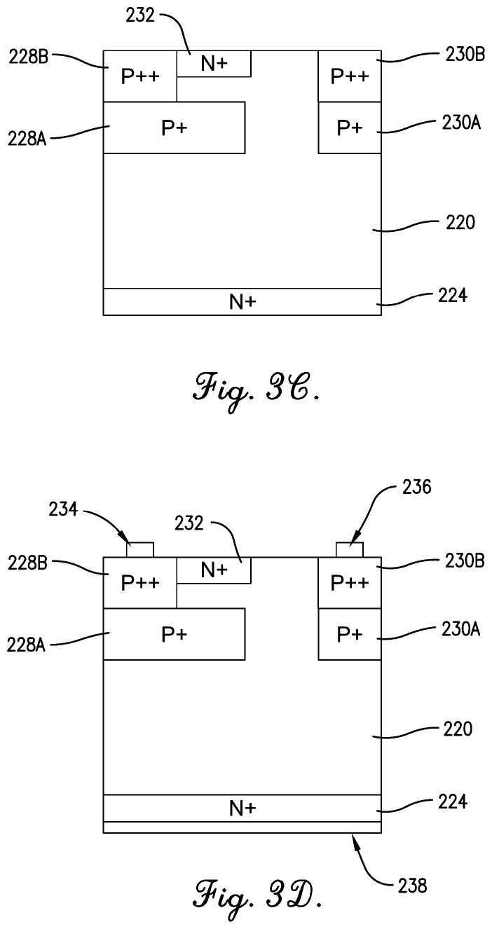

Referring to FIG. 2, an example of a method 120 of manufacturing a FET with a shielded source, such as the planar JFET 18 of FIG. 1, may include the operations set forth below. Referring additionally to FIGS. 3A-D, example results are shown of the operations of the method 120 and intermediate stages of production of the JFET 18.

A drain substrate material 224 may be provided, as shown in 122 as seen in FIG. 3A. The drain substrate material 224 may be N+ material. The drain substrate material 224 may become the drain 24.

A volume of semiconductor material 220 may be grown or otherwise provided on the drain substrate material 224, as shown in 124 and seen in FIG. 3A. The volume of semiconductor material 224 may be N-type material. The volume of semiconductor material 220 may include a first end, a second end, a first side, and a second side, wherein the substrate material 224, and therefore the drain 24, may be located at the second end of the volume of semiconductor material 220.

A lower first structure of doped material 228A may be implanted or otherwise provided at the first side of the volume of semiconductor material and extending into the volume of semiconductor material 220 toward the second side, as shown in 126 and seen in FIG. 3A. The lower first structure of doped material 228A may be P+ material. The lower first structure of doped material 228A may become the lower first gate component 28A.

A lower second structure of doped material 230A may be implanted or otherwise provided at the second side of the volume of semiconductor material 220 and spaced apart from the lower first structure of doped material 228A, as shown in 128 and seen in FIG. 3A. The lower second structure of doped material 230A may be P+ material. The lower second structure of doped material 230A may become the lower second gate component 30A. A horizontal spacing of the lower first structure of doped material 228A from the lower second structure of doped material 230A may be between one-half (0.5) and one-and-one-half (1.5) micrometers. A lower limit of the lower first structure of doped material 228A may be coplanar with a lower limit of the lower second structure of doped material 230A.

An upper first structure of doped material 228B may be implanted or otherwise provided at the first side of the volume of semiconductor material and above the lower first structure 228A, as shown in 130 and seen in FIG. 3B. The upper first structure of doped material 228B may be P++ material. The upper first structure of doped material 228B may become the upper first gate component 28B.

An upper second structure of doped material 230B may be implanted or otherwise provided at the second side of the volume of semiconductor material 220 and above the lower second structure 230A, as shown in 132 and seen in FIG. 3B. The upper second structure of doped material 230B may be P++ material. The upper second structure of doped material 230B may become the upper second gate component 30A.

A source structure of doped material 222 may be implanted or otherwise provided at the first end of the volume of semiconductor material 220, adjacent to the upper first structure of doped material 228B, above and spaced apart from the lower first structure of doped material 228A, and spaced apart from the upper second structure of doped material 230B, as shown in 134 and seen in FIG. 3C. The source structure of doped material 222 may be N+ material. The source structure of doped material 222 may become the source 22. A vertical spacing between the source structure of doped material 222 and the lower first structure of doped material 228A may be between one-half (0.5) and three-quarters (0.75) micrometers.

Thus, the lower first structure of doped material 228A (i.e., the lower first gate component 28A) extends beneath the source structure of doped material 222 (i.e., the source 22) so as to be positioned partially between the source structure of doped material 222 and the drain substrate material 224 (i.e., the drain 24) and shielding the source structure of doped material 222 and creating a turn in the channel 26 around the lower first structure of doped material 228A, and the channel 26 passes between the lower first structure of doped material 228A and the lower second structure of doped material 230A.

Electrical terminals 234, 236, 238 may be added to exposed surfaces to provide electrical connection to the source 22 and the second gate 30 (which may share a single terminal), the first gate 28, and the drain 24, as seen in FIG. 3D. Those of ordinary skill in the art will appreciate that, although portions (or components) of the first and second gates have been referenced herein with subsequent implantation steps being performed to form such gate portions, certain aspects may alternatively include additional steps to form additional gate portions or the gates may each be formed by a single formation (or implantation) process.

Additional processing may be performed as desired.

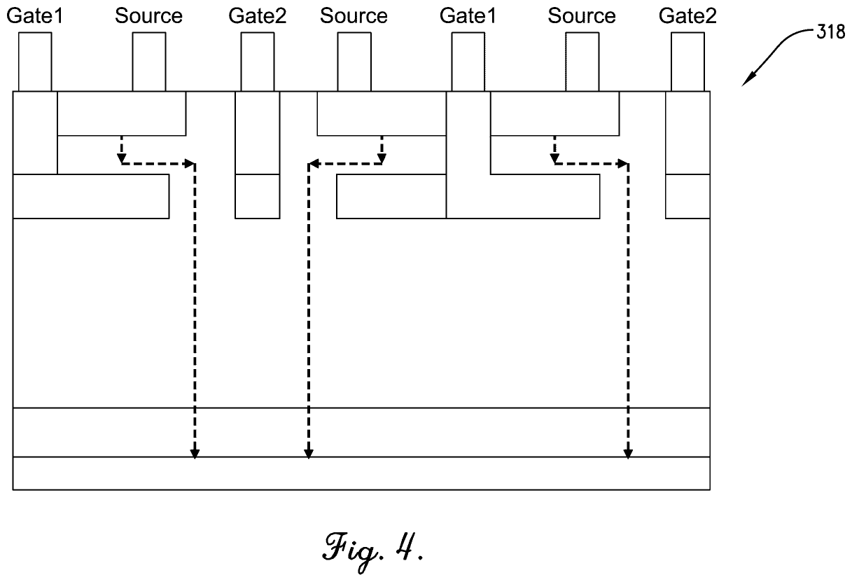

The method may be employed to simultaneously produce a plurality of instances 320, or unit cells of the planar JFET 18 with a shielded source, as shown in FIG. 4. Yet further, the volume of semiconductor may be further extended laterally (leftward and rightward when viewing FIG. 4) beyond the bounds illustrated in the drawing to present additional semiconductor material in which additional devices (similarly constructed JFETs or totally different devices (such as MOSFETs, Schottky barrier diodes, alternatively constructed JFETs, etc.)) are located. The semiconductor material may similarly extend inwardly or outwardly (relative to the lateral or cross-sectional direction depicted in FIG. 4.) to present additional devices in a direction transverse to the lateral direction.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide (Al2O3), hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 1×10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A field-effect transistor comprising:
a volume of semiconductor material including vertically spaced apart first and second ends and laterally spaced apart first and second sides;
a source located at the first end of the volume of semiconductor material;
a drain;
a channel extending between the source and the drain;
laterally spaced apart first and second gates, with the source being located between the gates,
the first gate including a lower first gate portion spaced below and extending beneath the source so as to create a turn in the channel around the lower first gate portion.

2. The field-effect transistor of claim 1,
the drain is located at the second end of the volume of semiconductor material, such that the lower first gate portion is vertically positioned at least in part between the source and the drain to thereby shield the source.

3. The field-effect transistor of claim 2,
the second gate including a lower second gate portion spaced laterally apart from the lower first gate portion, wherein the channel passes between the lower first gate portion and the lower second gate portion.

4. The field-effect transistor of claim 3,
a lateral spacing of the lower first gate portion from the lower second gate portion is between one-half (0.5) and one-and-one-half (1.5) micrometers.

5. The field-effect transistor of claim 3,
a lower limit of the lower first gate portion is coplanar with a lower limit of the lower second gate portion.

6. The field-effect transistor of claim 3,
the first gate including an upper first gate portion extending between the lower first gate portion and the first end of the volume of semiconductor material,
the second gate including an upper second gate portion extending between the lower second gate portion and the first end of the volume of semiconductor material.

7. The field-effect transistor of claim 6,
the source being laterally spaced from the upper second gate portion.

8. The field-effect transistor of claim 6,
the source abutting the upper first gate portion.

9. The field-effect transistor of claim 8,
the source being laterally spaced from the upper second gate portion.

10. The field-effect transistor of claim 9,
a spacing between the source and the upper second gate portion being less than a spacing between the lower first and second gate portions.

11. The field-effect transistor of claim 9,
a lower limit of the lower first gate portion is coplanar with a lower limit of the lower second gate portion.

12. The field-effect transistor of claim 1,
the field-effect transistor wherein the first and second gates are in direct contact with the channel, such that the field-effect transistor is a junction field-effect transistor.

13. The field-effect transistor of claim 1,
the field-effect transistor has a planar configuration, and the left and right first gate structures are located at the first end of the volume of semiconductor material.

14. The field-effect transistor of claim 1,
a vertical spacing between the source and the lower first gate portion is between one-half (0.5) and three-quarters (0.75) micrometers.

15. A method of making a junction field-effect transistor with a shielded source, the method comprising:
growing a volume of semiconductor material to include vertically spaced apart first and second ends and laterally spaced apart first and second sides;
implanting a first gate at the first side of the volume of semiconductor material;
implanting a second gate at the second side of the volume of semiconductor material spaced apart from the lower first gate component; and
implanting a source at the first end of the volume of semiconductor material between the first and second gates,
the step of implanting the first gate includes implanting a lower first gate portion at a location spaced below and extending beneath the source so as to create a turn in the channel around the lower first gate portion.

16. The method of claim 15,
the step of providing the drain includes providing a substrate material,
the step of growing the volume of semiconductor material includes growing the volume of semiconductor material on the substrate, with the substrate material forming the drain at the second end of the volume of semiconductor material, and the lower first gate portion is vertically positioned at least in part between the source and the drain to thereby shield the source.

17. The method of claim 16,
the step of implanting the first gate includes implanting an upper first gate portion at the first side of the volume of semiconductor material, with the upper first gate portion extending between the lower first gate portion and the first end of the volume of semiconductor material,
step of implanting the second gate includes
implanting a lower second gate portion spaced from the lower first gate portion, and
implanting a upper second gate portion spaced from the upper first gate portion, with the upper second gate portion extending between the lower second gate portion and the first end of the volume of semiconductor material.

18. The method of claim 17,
the step of implanting the source includes abutting the source against the upper first gate portion and spacing the source from the upper second gate portion.

19. The method of claim 18,
the steps of implanting the source and the lower first gate portion being performed so that a vertical spacing between the source and the lower first gate portion is between one-half (0.5) and three-quarters (0.75) micrometers.

20. The method of claim 19,
the steps of implanting the lower first and second gate portions being performed such that a lower limit of the lower first and second gate portions are coplanar and a horizontal spacing between the lower first and second gate portions is between one-half (0.5) and one-and-one-half (1.5) micrometers.
